(19) United States
(12) Patent Application Publication
(10) Pub. No.: US 2002/0085405 A1
(43) Pub. Date: Jul. 4, 2002

(54) Memory architecture with controllable bitline lengths

(76) Inventors: Gerhard Mueller, Meitingen (DE); Toshiaki Kirihata, Poughkeepsie, NY (US)

Correspondence Address: Siemens Corporation, Intellectual Property Department, 186 Wood Avenue South, Iselin, NJ, 08830, US

(21) Appl. No.: 09/751,480

(22) Filed: Dec. 28, 2000

(51) Int. Cl. G11C 5/06

(52) U.S. Cl. 365/63

(57) ABSTRACT

A bitline architecture having bitlines with electrically controllable bitline lengths is described. The bitlines are provided with a switch which selectively couples or decouples local bitline segments of a bitline, depending on the need to execute the memory access. Bitlines with controllable bitline lengths can result in a reduction in power consumption without additional sense amplifiers or an additional metal layer.

### FIELD OF THE INVENTION

The present invention generally relates to memory integrated circuits. More particularly, the present invention relates to memory integrated circuits with controllable bitline lengths.

### BACKGROUND OF THE INVENTION

In a memory integrated circuit (IC), an array of memory cells are interconnected by wordlines in the row direction and bitlines in the column direction. To read data from the memory cells, sense amplifiers are provided. A pair of bitlines is coupled to a sense amplifier. The bitline on which the memory cell from which data is to be read is referred to as the “bitline true” and the other bitline of the pair is referred to as the “bitline complement”. The bitlines are precharged to a predefined voltage level (V_{equ}). After the bitlines are precharged, the selected memory cell is coupled to the bitline, creating a differential voltage between the bitline pair. Depending on the data stored in the selected memory cell, the differential voltage is either positive or negative. The differential voltage is sensed and amplified by the sense amplifier.

Hierarchical bitline architectures have been proposed in memory ICs. Hierarchical bitline architectures are particularly useful in increasing bitline lengths without incurring significantly higher power consumption which is normally associated with larger bitline capacitances due to longer bitline lengths. FIG. 1 shows an embodiment of a hierarchical bit line architecture 100. A bitline includes local bitline segments 120 and a master bitline segment 130. Illustratively, the bitline includes first and second local bitline segments 120a-b. The master bitline is coupled to a sense amplifier 140 for sensing of a differential signal on a bitline pair. Typically, the local bitlines comprise about half the number of memory cells of the bitline. The first and second local bitline segments are selectively coupled to the master bitline via first and second local bitline switches 125a-b. However, conventional hierarchical bitline architectures require an additional metal layer due to the master bitline, which increases manufacturing complexity and cost.

As evident from the foregoing discussion, it is desirable to provide a memory IC having a bitline architecture which facilitates longer bitline lengths without the need for an additional metal layer.

### SUMMARY OF THE INVENTION

The invention relates to bitline architectures. More paritcularly, the invention relates to bitlines with electrically controllable bitline lengths. In one embodiment, electrically controllable bitline length is achieved by providing bitlines with n bitline switches, where n is a whole number equal to at least 1. The n switches, which comprise for example a transistor, divide the bitline into n+1 local bitline segments. By providing bitlines with electrically controllable lengths, a reduction in power consumption can be achieved without the need to provide additional sense amplifiers or an additional metal layer, as required in conventional hierarchical bitline architectures.

### BRIEF DESCRIPTION OF THE DRAWINGS

FIG. 1 shows a conventional hierarchical bitline architecture; and

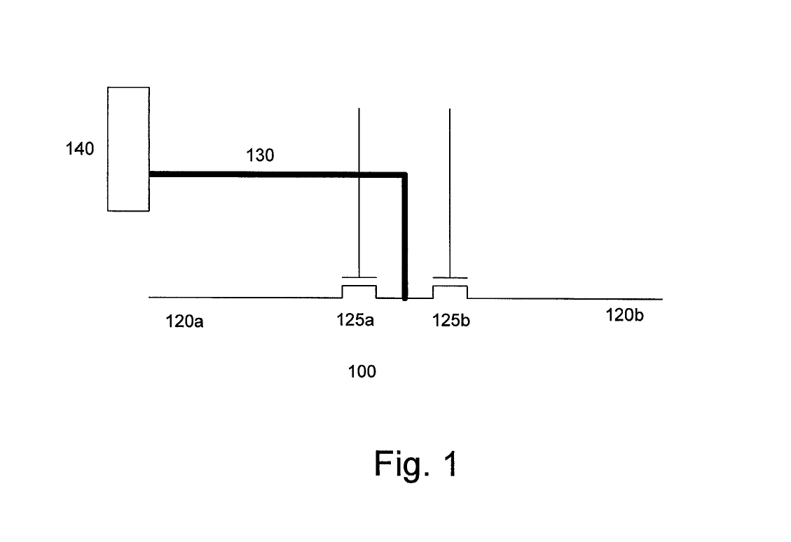

FIG. 2 shows an embodiment of the invention.

### DESCRIPTION OF THE INVENTION

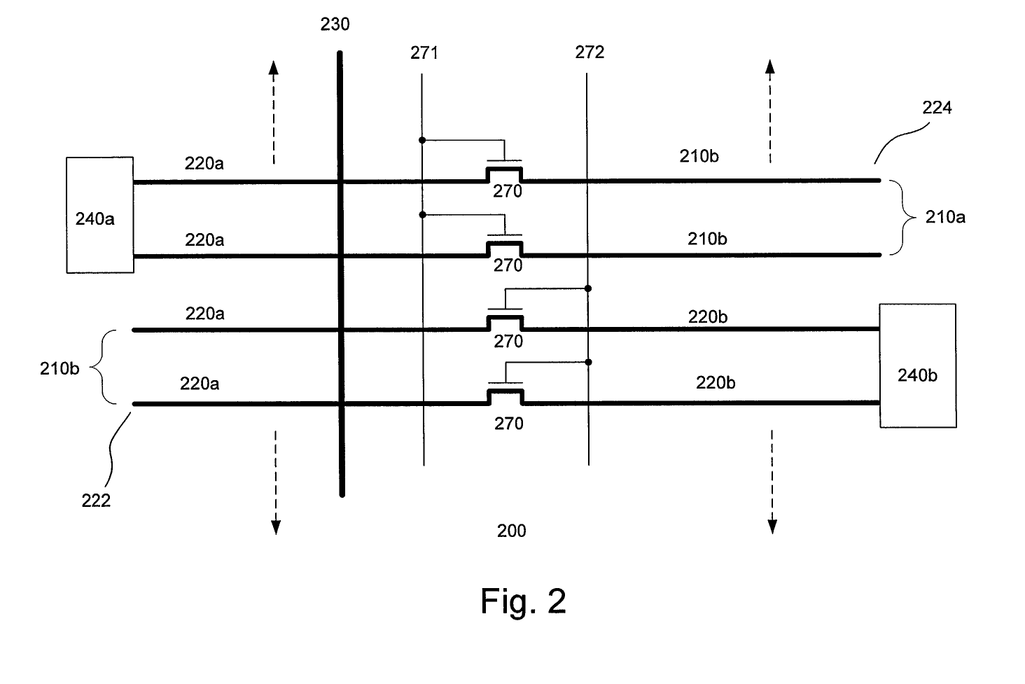

FIG. 2 shows a portion of a memory array 200 in accordance with one embodiment of the invention. A plurality of memory cells interconnected by bitlines 220 and wordlines are provided. In one embodiment, the bitlines are grouped into bitline pairs 210, with each pair coupled to a sense amplifier 240. As shown, the bitlines are organized as a folded bitline architecture in which the bitlines of the bitline pairs are within the same block. Typically, the bitlines of the bitline pairs are adjacent to each other. Other bitline architectures, such as folded or open-folded, are also useful. In one embodiment, every other bitline pair 210a is provided with a sense amplifier coupled to first ends 222 of the bitlines while alternate bitline pairs 210b have sense amplifiers coupled to second ends 224 of the bitlines.

The bitlines each comprises an electrical bitline switch 270. The terminals of the bitline switch are coupled to first and second local bitline segments 220a-b of the bitlines. Providing more than one bitline switch per bitline can also be useful for coupling n+1 local bitline segments, where n=the number of bitline switches per bitline. The local bitline segments can be substantially equal in length (e.g., same number of memory cells). The bitlines can also be separated into local bitline segments having different lengths.

In one embodiment, the electrical bitline switches comprise transistors, such as n-FETs. Other types of transistors, such as p-FETs or a combination thereof, are also useful. A control signal controls the operation of the switch. An active control signal causes the switch to couple the local bitline segments together; an inactive control signal causes the switch to isolate the bitline segments from each other.

The bitline switches enable the lengths of the bitlines to be electrically changed. The bitline lengths are changed as necessary to facilitate a memory access, such as a read, a write, or a refresh. In one embodiment, alternate bitline pairs are respectively controlled by first and second control signals 271 and 272 (e.g., switches of bitline pairs 210a are controlled by the first control signal 271 and switches of bitline pairs 210b are controlled by the second control signal 272). Such an arrangement results in about half the bitline switches of the array block or bank being activated and the other half being deactivated. This effectively reduces the overall capacitance of the bitlines in the array block or bank, thereby reducing power consumption. The reduction in power consumption is achieved without the need for an additional metal layer as required in conventional hierarchical bitline architectures.

To illustrate this point, assume that a memory access selects a wordline 230. To access the memory cells on the selected wordline, sense amplifiers 240a would only need to be coupled to local bitline segments 220a (inactive first control signal) while sense amplifiers 240b are coupled to both the local segments 220a and 220b of bitline pairs 210b (active second control signal). As a result, sense amplifiers 240a would see a bitline capacitance equal to that of about one local bitline segement (bitline segments 210a) while the sense amplifiers 240b would see a bitline capacitance equal to that of about two local bitline segments (220a and 220b). Such an arrangement can give rise to a reduction in sensing current of about 25% over memory architectures without electrically controllable bitline lengths. This power savings is achieved without the need for additional sense amplifiers or an additional metal layer.

In an alternative embodiment, the bitline switches of the first bitline pairs comprise a first type of FETs (e.g., n-FETs) and the bitline switches of the second bitline piars comprise a second type of FETs (e.g., p-FETs). By providing different types of FETs for the first and second bitline pairs, a single control signal can be used to control the bitline switches of the first and second bitline pairs to operate in a push-pull configuration.

While the invention has been particularly shown and described with reference to various embodiments, it will be recognized by those skilled in the art that modifications and changes may be made to the present invention without departing from the spirit and scope thereof. The scope of the invention should therefore be determined not with reference to the above description but with reference to the appended claims along with their full scope of equivalents.

What is claim is:

1. A memory device comprising:
a bitline having at least first and second local bitline segments, wherein the local bitline segments comprises first and second ends;
a sense amplifier coupled to a first end of the first bitline segment; and
an electronic switch having first and second terminals, the second ends of the first and second local bitlines are respectively coupled to the first and second terminals, the electronic switch selectively coupling or decoupling the first and second terminals together to couple or decouple the first and second local bitline segments, wherein when the bitline segments are decoupled, the bitline capacitance is reduced.

2. The memory device of claim 1 wherein the electronic switch comprises a FET.

3. The memory device of claim 2 wherein the electronic switch comprises an n-FET.

4. The memory device of claim 1 wherein the local bitline segments are about equal in length.

5. The memory device of claim 1, 2, 3, or 4 wherein the local bitline segments comprise memory cells coupled thereto.

6. The memory device of claim 5 wherein the electronic switch is activated to couple the first and second local bitline segments if a memory cell on the second local bitline segment is selected.

7. The memory device of claim 6 wherein the electronic switch is deactivated to isolate the first and second local bitline segments from each other if a memory cell on the first local bitline segment is selected.

8. The memory device of claim 7 wherein reduced bitline capacitance is achieved without an additional metal layer.

9. The memory device of claim 5 wherein reduced bitline capacitance is achieved without an additional metal layer.

10. The memory device of claim 6 wherein reduced bitline capacitance is achieved without an additional metal layer.
